(19) United States
(12) Patent Application Publication
(10) Pub. No.: US 2025/0015556 A1
(43) Pub. Date: Jan. 9, 2025

(54) LIGHT-EMITTING DEVICE, LIGHT-EMITTING MODULE, AND METHOD FOR MANUFACTURING LIGHT-EMITTING DEVICE

(71) Applicant: NICHIA CORPORATION, Anan-shi (JP)

(72) Inventor: Takuya HASHIMOTO, Tokushima-shi (JP)

(21) Appl. No.: 18/761,643

(22) Filed: Jul. 2, 2024

(30) Foreign Application Priority Data
Jul. 3, 2023 (JP) 2023-109495

(51) Int. Cl. H01S 5/02257; H01S 5/02255

(52) U.S. Cl. CPC H01S 5/02257; H01S 5/02255; H01S 2301/18

(57) ABSTRACT

A light-emitting device includes a package, a light-emitting element, a first spacer, an optical member, and a first bonding portion. The package includes a lid body having an upper surface. The light-emitting element is disposed in an internal space of the package. The first spacer is disposed on the upper surface of the lid body and has an upper surface. The optical member is disposed above the lid body and has an upper surface and a lower surface. The first bonding portion bonds the lid body and the optical member. The first bonding portion is arranged between the upper surface of the lid body and the lower surface of the optical member and between the upper surface of the first spacer and the lower surface of the optical member.

### CROSS-REFERENCE TO RELATED APPLICATIONS

This application claims priority to Japanese Patent Application No. 2023-109495 filed on Jul. 3, 2023, the disclosure of which is hereby incorporated herein by reference in its entirety.

### BACKGROUND

The present invention relates to a light-emitting device, a light-emitting module, and a method for manufacturing a light-emitting device.

Japanese Patent Publication No. 2022-123425 discloses a light-emitting device including a light-emitting element, a package, a wave plate, and a lens member, in which the light-emitting element is disposed in an internal space of the package, and the wave plate is provided between the package and the lens member.

### SUMMARY

When an optical member such as a wave plate is bonded onto a package, it is preferable in some cases to suppress an adhesive from obstructing an optical path of light. Meanwhile, when a light-emitting device is reduced in size, a region where the adhesive can be provided may also be limited.

Disclosed is a structure that can bond an object by appropriately disposing an adhesive.

A light-emitting device disclosed in an embodiment includes a package, a light-emitting element, a first spacer, an optical member, and a first bonding portion. The package includes a lid body having an upper surface. The light-emitting element is disposed in an internal space of the package. The first spacer is disposed on the upper surface of the lid body and has an upper surface. The optical member is disposed above the lid body and has an upper surface and a lower surface. The first bonding portion bonds the lid body and the optical member. The first bonding portion is arranged between the upper surface of the lid body and the lower surface of the optical member and between the upper surface of the first spacer and the lower surface of the optical member.

A light-emitting module disclosed in an embodiment includes the light-emitting device described above as a first light-emitting device, a second light-emitting device including no wave plate, and a light guide plate on which light emitted from the first light-emitting device and light emitted from the second light-emitting device are incident in a state in which the lights have the same polarization direction and the same fast axis direction. The first light-emitting device and the second light-emitting device are aligned in the fast axis direction.

A method for manufacturing a light-emitting device disclosed in an embodiment includes: providing a package including a lid body having an upper surface, a light-emitting element disposed in an internal space of the package, and a first spacer disposed on the upper surface of the lid body and having an upper surface; providing an adhesive to cover the upper surface of the first spacer in a top view; and bonding the upper surface of the lid body to a lower surface of an optical member via the adhesive.

In at least one of one or more of the disclosed embodiments, it is possible to realize a light-emitting device that can suppress an adhesive from obstructing an optical path of light.

### BRIEF DESCRIPTION OF DRAWINGS

FIG. 1 is a schematic perspective view of a light-emitting device according to a first embodiment.

FIG. 2 is a schematic side view of the light-emitting device according to the first embodiment.

FIG. 3 is a schematic cross-sectional view taken along line III-III in FIG. 1.

FIG. 4 is a schematic cross-sectional view taken along line IV-IV in FIG. 1.

FIG. 5 is an enlarged view for illustrating a state of a spacer and a bonding portion in the light-emitting device according to the first embodiment.

FIG. 6 is a schematic perspective view of the light-emitting device according to the first embodiment, with an optical member being transparently illustrated.

FIG. 7A is a schematic top view of the light-emitting device according to the first embodiment, with the optical member being transparently illustrated.

FIG. 7B is a partially enlarged view of FIG. 7A.

FIG. 8 is a schematic top view for illustrating a positional relationship between a base and the positions of the spacer and the bonding portion in the light-emitting device according to the first embodiment.

FIG. 9 is a schematic perspective view illustrating an internal structure of a package of the light-emitting device according to the first embodiment.

FIG. 10 is a schematic top view illustrating the internal structure of the package of the light-emitting device according to the first embodiment.

FIG. 11 is a schematic bottom view of the package according to the first embodiment.

FIG. 12 is a schematic top view illustrating an arrangement state of a semiconductor laser element and a submount according to the first embodiment.

FIG. 13 is a schematic side view illustrating the arrangement state of the semiconductor laser element and the submount according to the first embodiment.

FIG. 14 is a schematic view for illustrating a step of providing an adhesive in the light-emitting device according to the first embodiment.

FIG. 15 is a schematic view illustrating an example of a position where an adhesive is provided in the light-emitting device according to the first embodiment.

FIG. 16 is a schematic view illustrating another example of a position where the adhesive is provided in the light-emitting device according to the first embodiment.

FIG. 17A is a schematic top view illustrating another example of the bonding portion formed in the light-emitting device according to the first embodiment.

FIG. 17B is a partially enlarged view of FIG. 17A.

FIG. 18 is a schematic view of a light-emitting module according to a second embodiment.

FIG. 19 is a schematic perspective view of a second light-emitting device included in the light-emitting module according to the second embodiment.

### DETAILED DESCRIPTIONS

In the present specification or the claims, polygons such as triangles and quadrangles, including shapes in which the corners of the polygon are rounded, beveled, chamfered, or coved, are referred to as polygons. A shape obtained by processing not only the corners (ends of a side) but also an intermediate portion of the side is similarly referred to as a polygon. That is, a shape that is partially processed while maintaining a generally polygon shape as a base is included in the interpretation of “polygon” described in the present specification and the claims.

The same applies not only to polygons but also to words representing specific shapes such as trapezoids, circles, protrusions, and recesses. The same applies when dealing with each side forming that shape. That is, even if processing is performed on a corner or an intermediate portion of a certain side, the interpretation of “side” includes the processed portion. When a “polygon” or “side” not partially processed is to be distinguished from a processed shape, “exact” will be added to the description as in, for example, “exact quadrangle”.

Further, in the present specification or the claims, descriptions such as upper and lower (upward/downward), left and right, surface and reverse, front and back (forward/backward), and near and far are used merely to describe the relative relationship of positions, orientations, and directions, and the expressions do not necessarily match an actual relationship at the time of use.

In the drawings, directions such as an X direction, a Y direction, and a Z direction may be indicated by using arrows. The directions of the arrows are consistent across multiple drawings of the same embodiment. In addition, in the drawings, the directions of the arrows marked with X, Y, and Z are the positive directions, and the opposite directions are the negative directions. For example, the direction marked with X at the tip of the arrow is the X direction and the positive direction. In the present specification, the direction that is the X direction and is the positive direction will be referred to as the “positive direction of X” and the direction opposite to this will be referred to as the “negative direction of X”. The term “X direction” includes both the positive direction and the negative direction. The same applies to the Y direction and the Z direction.

In addition, in the present specification, when a certain object is specified as “one or more” and the object is described, an embodiment in which the object is one and an embodiment in which the object is plural are collectively described. Thus, a description specified as “one or more” supports every case of an embodiment including one or more objects, an embodiment including at least one object, and an embodiment including a plurality of objects.

In addition, in the present specification, the description illustrating “one or each” object is a description summarizing a description of one object in an embodiment including the one object, a description of one object in an embodiment including a plurality of objects, and a description of each of a plurality of objects in an embodiment including the plurality of objects. Thus, the description illustrating “one or each” object supports every case of an embodiment including one object in which the one object satisfies the described content, an embodiment including a plurality of objects in which, among these objects, at least one of the objects satisfies the described content, and an embodiment including a plurality of objects in which each of these plurality of objects satisfies the described content, and an embodiment including one or more objects in which all of the objects satisfy the described content.

The term “member” or “portion” may be used to describe, for example, a component in the present specification. The term “member” refers to an object physically treated alone. The object physically treated alone can be an object treated as one part in a manufacturing process. Meanwhile, the term “portion” refers to an object that need not be physically treated alone. For example, the term “portion” is used when part of one member is partially considered, or a plurality of members are collectively considered as one object.

The distinction between “member” and “portion” described above does not indicate an intention to consciously limit the scope of claim in interpretation of the doctrine of equivalents. That is, even when a component described as “member” is present in the claims, this does not mean that the applicant recognizes that physically treating the component alone is essential in the application of the present invention.

In the present specification or the claims, when a plurality of components are present and these components are to be indicated separately, the components may be distinguished by adding the terms “first” and “second” at the beginning of the names of the components. Objects to be distinguished may differ between the present specification and the claims. Thus, even when a component in the claims is given the same term as that in the present specification, the object identified by that component is not the same across the present specification and the claims in some cases.

For example, when components distinguished by being termed “first”, “second”, and “third” are present in the present specification, and when components given the terms “first” and “third” in the present specification are described in the claims, these components may be distinguished by being denoted as “first” and “second” in the claims for ease of understanding. In such a case, the components denoted as “first” and “second” in the claims refer to the components termed “first” and “third” in the specification, respectively. This rule applies to not only components but also other objects in a reasonable and flexible manner.

Embodiments for implementing the present invention will be described below. Specific embodiments for implementing the present invention will be described below with reference to the drawings. Embodiments for implementing the present invention are not limited to the specific embodiments. That is, the embodiments illustrated by the drawings are not the only form in which the present invention is realized. Sizes and positional relationships of members illustrated in each of the drawings may sometimes be exaggerated in order to facilitate understanding.

### First Embodiment

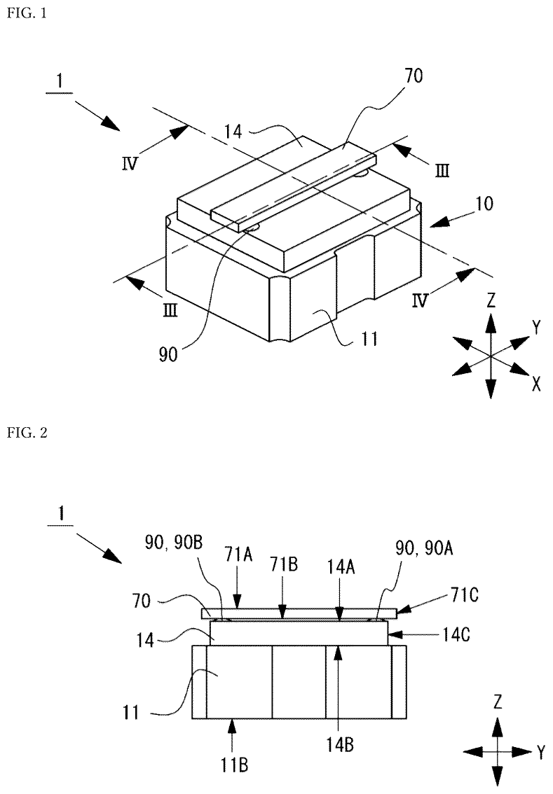

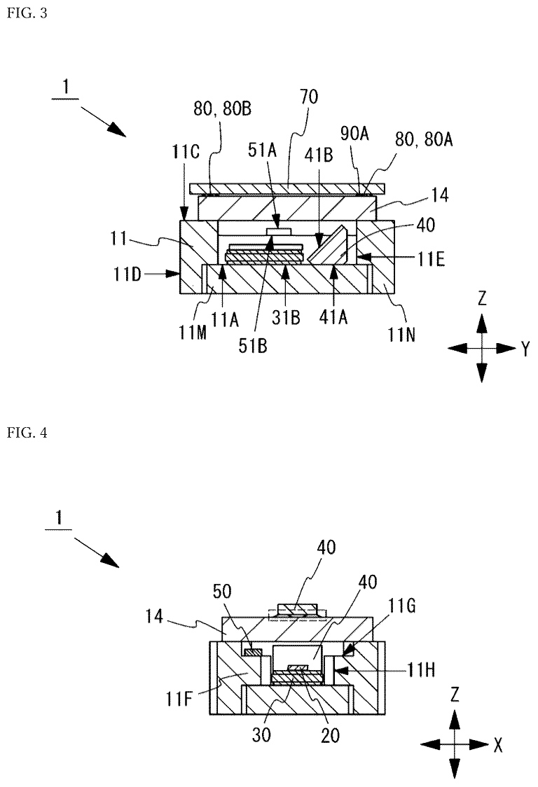

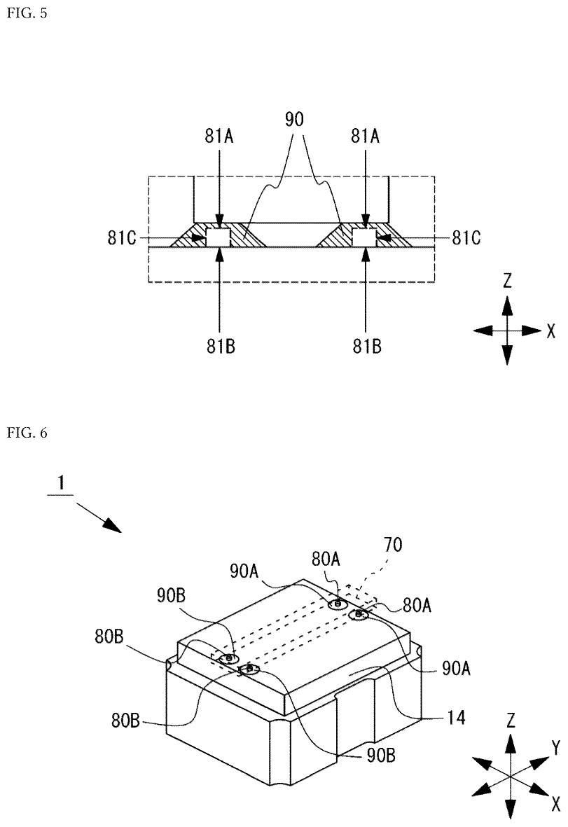

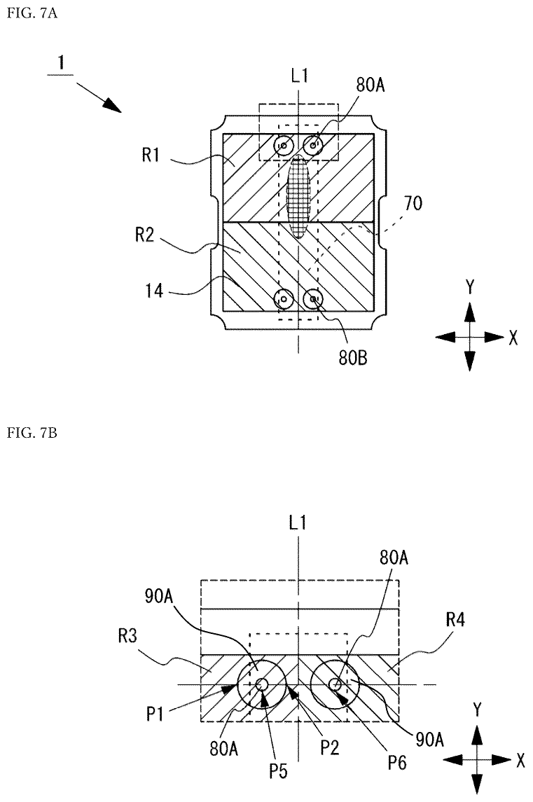

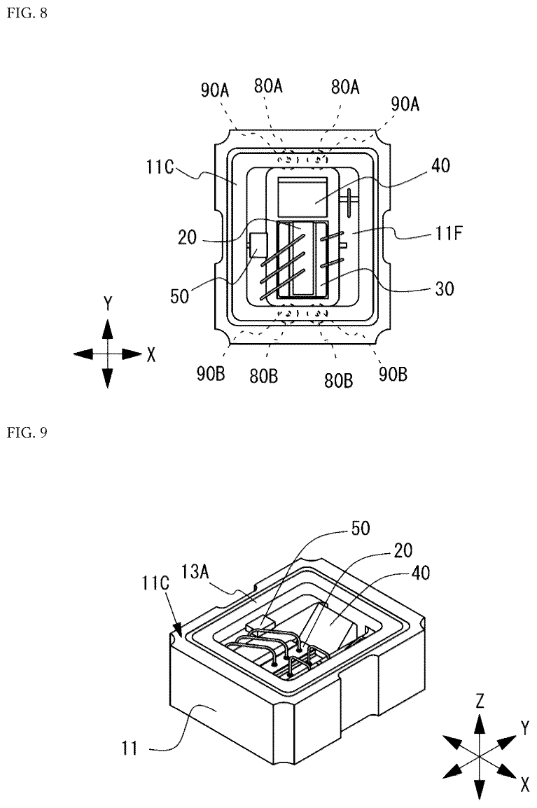

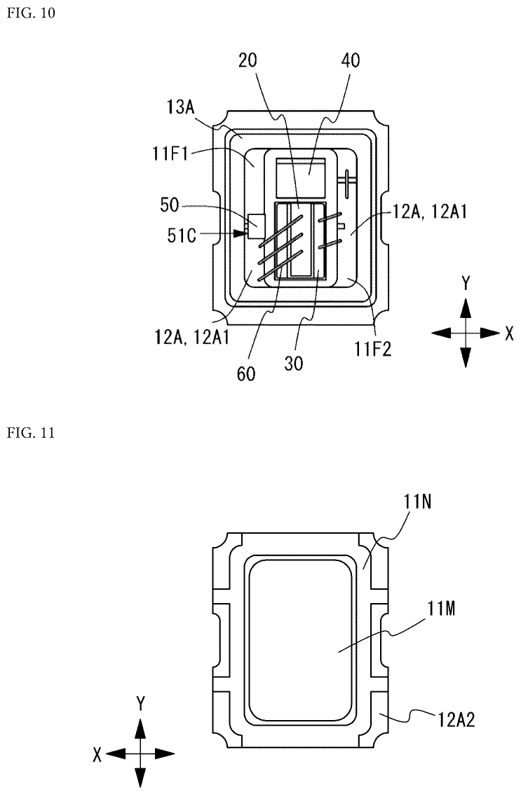

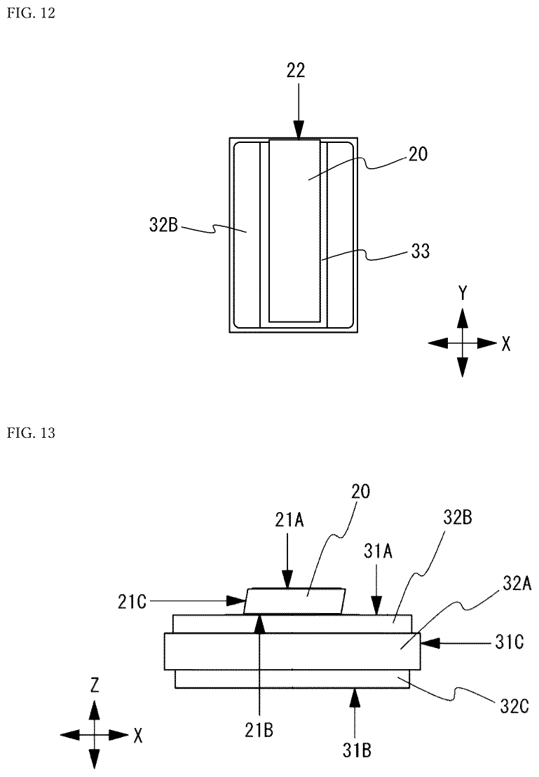

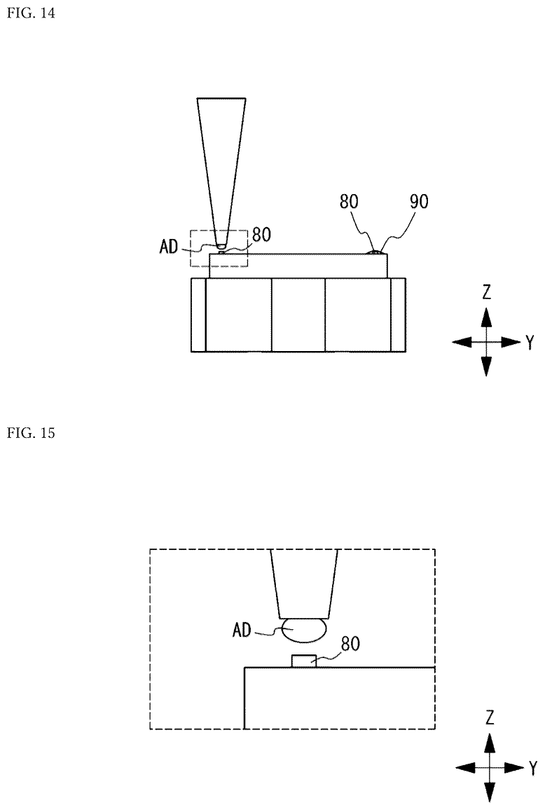

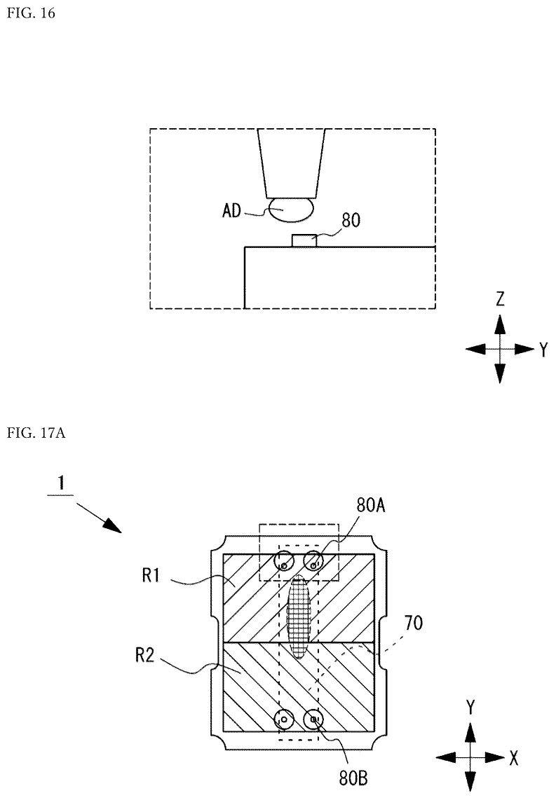

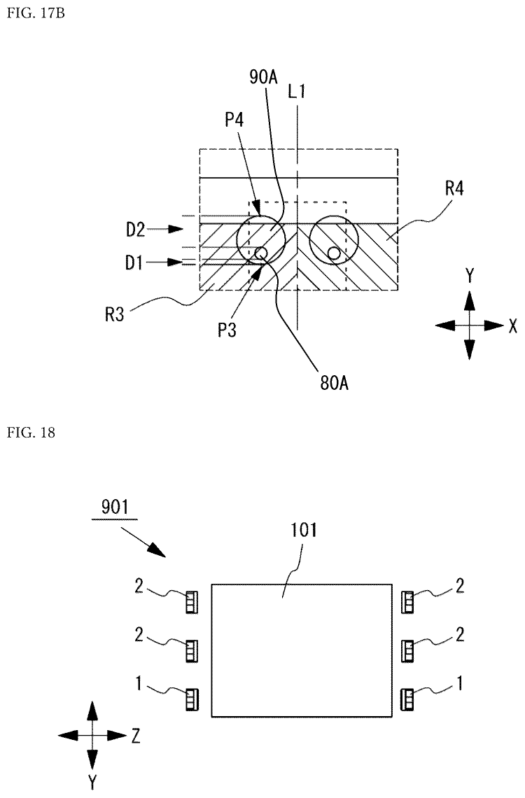

A light-emitting device 1 according to a first embodiment will now be described. FIGS. 1 to 17B are views for illustrating an exemplary embodiment of the light-emitting device 1. FIG. 1 is a schematic perspective view of the light-emitting device 1. FIG. 2 is a schematic side view of the light-emitting device 1. FIG. 3 is a schematic cross-sectional view taken along line III-III in FIG. 1. FIG. 4 is a schematic cross-sectional view taken along line IV-IV in FIG. 1. A rectangular broken line indicates a region illustrated in an enlarged manner in FIG. 5. FIG. 5 is an enlarged view for illustrating a state of a spacer 80 and a bonding portion 90 in the light-emitting device 1. For ease of viewing, the bonding portion 90 is indicated by hatching, and the spacer 80 included in the bonding portion 90 is indicated by a broken line. FIG. 6 is a schematic perspective view of the light-emitting device 1, with an optical member 70 being transparently illustrated. The transparently illustrated optical member 70 is indicated by a dotted line. FIG. 7A is a schematic top view of the light-emitting device 1, with the optical member 70 being transparently illustrated. A rectangular broken line indicates a region illustrated in an enlarged manner in FIG. 7B. In addition, a first region R1 and a second region R2 are respectively indicated by hatching with oblique lines, and light of a main portion irradiated on an upper surface 14A or a lower surface 71B is indicated by hatching with half-tone dots. In addition, in a portion where the first region R1 and the second region R2 overlap the irradiation region of the light of the main portion, only hatching of the irradiation region is illustrated. FIG. 7B is an enlarged view of a region where the spacer 80 and the bonding portion 90 are disposed. A third region R3 and a fourth region R4 are indicated by hatching. FIG. 8 is a schematic top view for illustrating a positional relationship between a base 11 and the positions of a first spacer 80A, a second spacer 80B, a first bonding portion 90A, and a second bonding portion 90B in the light-emitting device 1. The spacers and the bonding portions are indicated by dotted lines. FIG. 9 is a schematic perspective view illustrating an internal structure of a package of the light-emitting device 1. FIG. 10 is a schematic top view illustrating the internal structure of the package of the light-emitting device 1. FIG. 11 is a schematic bottom view of the package 10. FIG. 12 is a schematic top view illustrating an arrangement state of a light-emitting element 20 and a submount 30. FIG. 13 is a schematic side view illustrating an arrangement state of the light-emitting element 20 and the submount 30. FIG. 14 is a schematic view for illustrating a step of providing an adhesive in the manufacture of the light-emitting device 1. A rectangular broken line indicates a region illustrated in an enlarged manner in FIGS. 15 and 16. FIG. 15 is a schematic view illustrating an example of an application position of an adhesive AD in the step of providing the adhesive. FIG. 16 is a schematic view illustrating another example of the application position of the adhesive AD in the step of providing the adhesive. FIG. 17A is a schematic top view illustrating a bonding portion formed when the adhesive is provided at the application position illustrated in FIG. 16. A rectangular broken line indicates a region illustrated in an enlarged manner in FIG. 17B. In addition, the first region R1 and the second region R2 are respectively indicated by hatching with oblique lines, and light of a main portion irradiated on the upper surface 14A or the lower surface 71B is indicated by hatching with half-tone dots. In addition, in a portion where the first region R1 and the second region R2 overlap the irradiation region of the light of the main portion, only hatching of the irradiation region is illustrated. FIG. 17B is an enlarged view of a region where the spacer 80 and the bonding portion 90 are disposed. The third region R3 and the fourth region R4 are indicated by hatching.

The light-emitting device 1 includes a plurality of components. The components include the package 10, one or more light-emitting elements 20, one or more submounts 30, one or more reflective members 40, one or more protective elements 50, and a plurality of wiring lines 60.

The light-emitting device 1 may include a component other than the components described above. For example, the light-emitting device 1 may further include a light-emitting element different from the one or more light-emitting elements 20. The light-emitting device 1 need not include some of the components described above.

Firstly, each of the components will be described.

### Package 10

The package 10 includes the base 11 and a lid body 14. The lid body 14 is bonded to the base 11 to form the package 10. An internal space in which other components are disposed is defined in the package 10. The internal space is a closed space surrounded by the base 11 and the lid body 14. The internal space can also be a sealed space in a vacuum or airtight state.

The outer edge shape of the package 10 in a top view is rectangular. This rectangular shape can be a rectangular shape with long sides and short sides. In the package 10 illustrated by the drawings, a short-side direction of the rectangular shape is the same direction as the X direction, and a long-side direction is the same direction as the Y direction. The outer edge shape of the package 10 in a top view need not be rectangular.

The internal space in which other components are disposed is formed in the package 10. The first upper surface 11A of the package 10 is a part of a region defining the internal space. In addition, inner lateral surfaces 11E and the lower surface 14B of the package 10 are a part of the region defining the internal space.

The base 11 has the first upper surface 11A and a lower surface 11B. The base 11 has a second upper surface 11C. The base 11 has one or more outer lateral surfaces 11D. The base 11 has one or more inner lateral surfaces 11E. The one or more outer lateral surfaces 11D meet the second upper surface 11C. The one or more outer lateral surfaces 11D meet the lower surface 11B. The one or more inner lateral surfaces 11E meet the second upper surface 11C.

The outer edge shape of the base 11 in a top view is rectangular. The outer edge shape of the base 11 in a top view is the outer edge shape of the package 10. The outer edge shape of the first upper surface 11A in a top view is rectangular. This rectangular shape can be a rectangular shape with long sides and short sides. The long-side direction of the first upper surface 11A is parallel to the long-side direction of the outer edge shape of the base 11. The outer edge shape of the first upper surface 11A in a top view need not be rectangular.

In a top view, the first upper surface 11A is surrounded by the second upper surface 11C. The second upper surface 11C is an annular surface surrounding the first upper surface 11A in a top view. The second upper surface 11C is a rectangular annular surface. Here, a frame defined by an inner edge of the second upper surface 11C is referred to as an inner frame of the second upper surface 11C, and a frame defined by an outer edge of the second upper surface 11C is referred to as an outer frame of the second upper surface 11C.

The base 11 has a recessed portion surrounded by the frame formed by the second upper surface 11C. The recessed portion defines a portion recessed downward from the second upper surface 11C in the base 11. The first upper surface 11A is a part of the recessed portion. The one or more inner lateral surfaces 11E are a part of the recessed portion. The second upper surface 11C is located above the first upper surface 11A.

The base 11 includes one or more step portions 11F. Each of the step portions 11F includes an upper surface 11G and a lateral surface 11H that meets the upper surface 11G and extends downward from the upper surface 11G. Here, one step portion 11F has only one upper surface 11G and only one lateral surface 11H. The upper surface 11G meets the inner lateral surface 11E. The lateral surface 11H meets the first upper surface 11A.

One or each of the step portions 11F is formed on an inner side of the inner frame of the second upper surface 11C in a top view. One or each of the step portions 11F is formed along a part of or the entire inner lateral surface 11E in a top view. In the base 11, the lateral surface 11H is an inner lateral surface, but the lateral surface 11H and the inner lateral surface 11E are different surfaces. One or each of the inner lateral surfaces 11E and one or each of the lateral surfaces 11H are perpendicular to the first upper surface 11A. The description “perpendicular” as used herein allows for a difference within +3 degrees.

The one or more step portions 11F can include a first step portion 11F1 and a second step portion 11F2. The first step portion 11F1 and the second step portion 11F2 are provided at positions where the respective lateral surfaces 11H are opposed to each other. The first step portion 11F1 and the second step portion 11F2 are provided on sides of the short sides of the inner frame of the second upper surface 11C.

The base 11 includes a base portion 11M and a frame portion 11N. The base portion 11M and the frame portion 11N may be members made of mutually different materials. The base 11 can be configured to include a base member corresponding to the base portion 11M and a frame member corresponding to the frame portion 11N.

The base portion 11M includes the first upper surface 11A. The frame portion 11N includes the second upper surface 11C. The frame portion 11N includes the one or more outer lateral surfaces 11D and the one or more inner lateral surfaces 11E. The frame portion 11N includes the one or more step portions 11F.

The lower surface of the base portion 11M constitutes a part or the entire region of the lower surface 11B of the base 11. When the lower surface of the base portion 11M constitutes a part of the region of the lower surface 11B of the base 11, the lower surface of the frame portion 11N constitutes the remaining region of the lower surface 11B of the base 11.

The base 11 includes a plurality of wiring portions 12A. The wiring portions 12A include one or more first wiring portions 12A1 disposed in the internal space of the package 10 and one or more second wiring portions 12A2 provided on the outer surface of the package 10.

One or each of the first wiring portions 12A1 is provided on the upper surface 11G of the step portion 11F. The base 11 includes the one or more first wiring portions 12A1 provided on the upper surface 11G of the first step portion 11F1. The base 11 includes the one or more first wiring portions 12A1 provided on the upper surface 11G of the second step portion 11F2.

One or each of the second wiring portions 12A2 is provided on the lower surface 11B of the package 10. One or each of the second wiring portions 12A2 is provided on the lower surface of the frame portion 11N. The second wiring portion 12A2 may be provided on an outer surface different from the lower surface 11B of the package 10.

When the base 11 is divided into two regions by a virtual line passing through the lateral surface 11H of the first step portion 11F1 and parallel to the lateral surface 11H in a top view, the base 11 has the one or more second wiring portions 12A2 provided on the lower surface 11B of the base 11 in a region including the upper surface 11G of the first step portion 11F1.

When the base 11 is divided into two regions by a virtual line passing through the lateral surface 11H of the second step portion 11F2 and parallel to the lateral surface 11H in a top view, the base 11 has the one or more second wiring portions 12A2 provided on the lower surface 11B of the base 11 in a region including the upper surface 11G of the second step portion 11F2.

In the base 11, one or each of the first wiring portions 12A1 is electrically connected to the second wiring portion 12A2. The one or more first wiring portions 12A1 are electrically connected to the mutually different second wiring portions 12A2.

The base 11 includes a bonding pattern 13A. The bonding pattern 13A is provided on the second upper surface 11C. The bonding pattern 13A is provided annularly. The bonding pattern 13A is provided in a rectangular annular shape. In a top view, the first upper surface 11A is surrounded by the bonding pattern 13A.

The base 11 can be formed using a ceramic as a main material, for example. Examples of the ceramic as the main material of the base 11 include aluminum nitride, silicon nitride, aluminum oxide, and silicon carbide.

The main material as used herein refers to a material that accounts for the greatest proportion of a target formed product in terms of mass or volume. When a target formed product is formed of a single material, the material is the main material. In other words, when a certain material is the main material, the proportion of the material may be 100%.

The base 11 may be formed using a base member and a frame member formed of main materials different from each other. The base member can be formed using a main material having excellent heat dissipation, for example, a metal or a composite containing a metal, graphite, or diamond. Examples of the metal as the main material of the base member include, for example, copper, aluminum, and iron. Examples of the composite containing the metal as the main material of the base member include, for example, copper-molybdenum or copper-tungsten. The frame member can be formed using, as a main material, for example, any of the ceramics exemplified above as the main material of the base 11.

The wiring portion 12A can be formed using a metal material as a main material, for example. Examples of the metal material as the main material of the wiring portion 12A include single-component metals, such as Cu, Ag, Ni, Au, Ti, Pt, Pd, Cr, and W, and alloys containing any of these metals. The wiring portion 12A can be constituted by one or more metal layers, for example.

The bonding pattern 13A can be formed using a metal material as a main material, for example. Examples of the metal material as the main material of the bonding pattern 13A include single-component metals, such as Cu, Ag, Ni, Au, Sn, Ti, and Pd, and alloys containing any of these metals. The bonding pattern 13A can be constituted by one or more metal layers, for example.

The lid body 14 has an upper surface 14A and a lower surface 14B. The lid body 14 also has one or more lateral surfaces 14C. The lid body 14 is formed of a flat plate with a rectangular parallelepiped shape. The lid body 14 does not necessarily have a rectangular parallelepiped shape.

The lid body 14 is bonded to the base 11. The lower surface 14B of the lid body 14 is bonded to the second upper surface 11C of the base 11. The lid body 14 is bonded to the bonding pattern 13A of the base 11. The lid body 14 is bonded to the base 11 via an adhesive.

In a top view, the lid body 14 is disposed inside the outer edge of the base 11. In a top view, the outer edge of the lid body 14 is disposed outside the inner frame of the second upper surface 11C of the base 11.

The lid body 14 has light transmissivity to transmit light. The description “light transmissivity” as used herein refers to that the transmittance of light incident on the lid body 14 is equal to or more than 80%. The lid body 14 may partially include a non-light transmitting region (a region with no light transmissivity).

The lid body 14 can be formed using glass as a main material, for example. The lid body 14 can also be formed using sapphire as a main material, for example.

### Light-Emitting Element 20

The light-emitting element 20 has an upper surface 21A, a lower surface 21B, and a plurality of lateral surfaces 21C. The shape of the upper surface 21A is rectangular. The rectangular shape is a rectangular shape having long sides and short sides. The outer shape of the light-emitting element 20 in a top view is rectangular. The rectangular shape is a rectangular shape having long sides and short sides. The shape of the upper surface 21A and the outer shape of the light-emitting element 20 in a top view are not limited thereto.

The light-emitting element 20 has a light-emitting surface 22 from which light is emitted. For example, the lateral surface 21C can serve as the light-emitting surface 22. The lateral surface 21C serving as the light-emitting surface 22 meets a short side of the upper surface 21A. Also, for example, the upper surface 21A can serve as the light-emitting surface 22. The light-emitting element 20 has one or more light-emitting surfaces 22.

As the light-emitting element 20, for example, a light-emitting element that emits blue light can be employed. Also, for example, as the light-emitting element 20, a light-emitting element that emits green light can be employed. Also, for example, as the light-emitting element 20, a light-emitting element that emits red light can be employed. As the light-emitting element 20, a light-emitting element that emits light of another color or another wavelength may be employed.

Here, blue light refers to light having a light emission peak wavelength within a range from 420 nm to 494 nm. Green light refers to light having a light emission peak wavelength within a range from 495 nm to 570 nm. Red light refers to light having a light emission peak wavelength within a range from 605 nm to 750 nm.

Examples of the light-emitting element 20 that emits blue light or the light-emitting element 20 that emits green light include a light-emitting element containing a nitride semiconductor. A GaN-based semiconductor, such as GaN, InGaN, or AlGaN, can be employed as the nitride semiconductor. Examples of the light-emitting element 20 that emits red light include a light-emitting element containing an InAlGaP-based semiconductor, a GaInP-based semiconductor, or a GaAs-based semiconductor, such as GaAs or AlGaAs.

As the light-emitting element 20, for example, a semiconductor laser element can be employed. As the light-emitting element 20, a single-emitter semiconductor laser element constituted by one emitter can be employed. Also, as the light-emitting element 20, a multi-emitter semiconductor laser element constituted by a plurality of emitters can be employed. The light-emitting element 20 is not limited to a semiconductor laser element, and may be, for example, a light-emitting diode.

Here, a semiconductor laser element as an example of the light-emitting element 20 will be described.

The semiconductor laser element emits a directional laser beam. Spreading divergent light is emitted from the light-emitting surface 22 of the semiconductor laser element. The light emitted from the semiconductor laser element forms a far-field pattern (hereinafter, referred to as an “FFP”) with an elliptical shape in a plane parallel to the light-emitting surface 22. The FFP indicates a shape or a light intensity distribution of the emitted light at a position spaced apart from the light-emitting surface of the semiconductor laser element.

Here, light passing through the center of the elliptical shape of the FFP, in other words, light having a peak intensity in the light intensity distribution of the FFP is referred to as light traveling along an optical axis or light passing through an optical axis. Based on the light intensity distribution of the FFP, light having an intensity that is equal to or more than 1/e² with respect to the peak intensity is referred to as a main portion of the light.

The FFP of the light emitted from the semiconductor laser element has an elliptical shape in which the length in a layering direction is greater than that in a direction perpendicular to the layering direction in the plane parallel to the light-emitting surface 22. The layering direction is a direction in which a plurality of semiconductor layers including an active layer are layered in the semiconductor laser element. The direction perpendicular to the layering direction can also be referred to as a plane direction of the semiconductor layer. Further, a major axis direction of the elliptical shape of the FFP can also be referred to as a fast axis direction of the semiconductor laser element, and a minor axis direction can also be referred to as a slow axis direction of the semiconductor laser element.

Based on the light intensity distribution of the FFP, an angle at which light having a light intensity of 1/e² of the peak light intensity spreads is referred to as a divergence angle of light of the semiconductor laser element. Here, the divergence angle of light is indicated as an angle formed by light having the peak light intensity (light passing through an optical axis) and light having a light intensity of 1/e² of the peak light intensity. In some cases, the divergence angle of light can also be determined based on, for example, the light intensity that is half of the peak light intensity, other than being determined based on the light intensity of 1/e² of the peak light intensity. In the description herein, the term “divergence angle of light” by itself refers to a divergence angle of light at the light intensity of 1/e² of the peak light intensity.

The divergence angle in the fast axis direction of the light emitted from the semiconductor laser element can be 15 degrees or more and less than 40 degrees. Also, the divergence angle of the light in the slow axis direction can be in a range from more than 0 degrees to 10 degrees. Also, the divergence angle of the light in the fast axis direction is greater than the divergence angle of the light in the slow axis direction.

For example, the divergence angle in the fast axis direction of blue light emitted from the semiconductor laser element can be in a range from 15 degrees to less than 30 degrees, and the divergence angle in the slow axis direction can be in a range from 2 degrees to less than 10 degrees. Also, for example, the divergence angle in the fast axis direction of green light emitted from the semiconductor laser element can be in a range from 15 degrees to less than 30 degrees, and the divergence angle in the slow axis direction can be in a range from 2 degrees to less than 10 degrees. Also, for example, the divergence angle in the fast axis direction of red light emitted from the semiconductor laser element can be in a range from 20 degrees to less than 40 degrees, and the divergence angle in the slow axis direction can be in a range from 3 degrees to less than 10 degrees.

### Submount 30

The submount 30 includes an upper surface 31A, a lower surface 31B, and one or more lateral surfaces 31C. It can be said that the upper surface 31A is a mounting surface on which other components are mounted. The shape of the upper surface 31A is rectangular. The rectangular shape of the upper surface 31A can have short sides and long sides. The shape of the upper surface 31A need not be rectangular.

The outer shape of the submount 30 in a top view is rectangular. The rectangular shape of the submount 30 can have short sides and long sides. The outer shape of the submount 30 in a top view need not be rectangular. The submount 30 can have an outer shape having a length in one direction (hereinafter, the direction is referred to as a lateral direction of the submount 30) smaller than a length in a direction (hereinafter, the direction is referred to as a longitudinal direction of the submount 30) perpendicular to the one direction in a top view. In the submount 30 illustrated by the drawings, the lateral direction is the same direction as the X direction, and the longitudinal direction is the same direction as the Y direction.

The submount 30 can include a substrate 32A and an upper metal member 32B. The submount 30 can further include a lower metal member 32C. The upper metal member 32B is provided on the upper surface side of the substrate 32A. The lower metal member 32C is provided on the lower surface side of the substrate 32A. The submount 30 further includes a wiring layer 33. The wiring layer 33 is provided on the upper metal member 32B.

The substrate 32A has an insulating property. The substrate 32A is formed of, for example, silicon nitride, aluminum nitride, or silicon carbide. It is preferable to select a ceramic with relatively good heat dissipation (having high thermal conductivity) as the main material of the substrate 32A.

A metal such as copper and aluminum is used as the main material of the upper metal member 32B. The upper metal member 32B includes one or more metal layers. The upper metal member 32B can include a plurality of metal layers formed of different metals as main materials.

A metal such as copper or aluminum is used as the main material of the lower metal member 32C. The lower metal member 32C includes one or more metal layers. The lower metal member 32C can include a plurality of metal layers formed of different metals as main materials.

The wiring layer 33 can be formed using a metal. For example, the wiring layer 33 can be formed using AuSn solder (a metal layer of AuSn).

For example, the length of the submount 30 in the short-side direction or the lateral direction is in a range from 700 μm to 1400 μm. The length of the submount 30 in the long-side direction or the longitudinal direction is in a range from 1200 μm to 2700 μm. The difference between the length in the longitudinal direction and the length in the lateral direction of the submount 30 is in a range from 100 μm to 2000 μm.

For example, the thickness of the submount 30 (the width in a direction perpendicular to the upper surface 31A) is in a range from 200 μm to 400 μm. Also, for example, the thickness of the substrate 32A is in a range from 100 μm to 300 μm. Also, for example, the thickness of the upper metal member 32B is in a range from 25 μm to 75 μm. Also, for example, the thickness of the lower metal member 32C is in a range from 25 μm to 75 μm. Also, for example, the thickness of the wiring layer 33 is in a range from 1 μm to 5 μm.

### Reflective Member 40

The reflective member 40 has a lower surface 41A, and a light-reflective surface 41B that reflects light. The light-reflective surface 41B is inclined with respect to the lower surface 41A. A straight line connecting a lower end and an upper end of the light-reflective surface 41B is inclined with respect to the lower surface 41A. An angle at which the light-reflective surface 41B is inclined with respect to the lower surface 41A is referred to as an inclination angle of the light-reflective surface 41B.

The light-reflective surface 41B is a flat surface. The light-reflective surface 41B may be a curved surface. The inclination angle of the light-reflective surface 41B is 45 degrees. The light-reflective surface 41B need not have an inclination angle of 45 degrees.

As the main material of the reflective member 40, glass or metal can be used. A heat-resistant material is preferably used as the main material of the reflective member 40. As the main material, for example, a glass such as quartz glass or borosilicate glass (BK7), or a metal such as Al can be used. The reflective member 40 can also be formed using Si as the main material.

When the main material is a reflective material such as Al, the light-reflective surface 41B can be formed of the main material. Instead of forming the light-reflective surface 41B with the main material, a general form of the reflective member 40 may be formed with the main material, and the light-reflective surface 41B may be formed on a surface of the general form. In this case, the light-reflective surface 41B can be formed using, for example, a layer of a metal such as Ag or Al, or a dielectric multilayer film of Ta₂O₅/SiO₂, TiO₂/SiO₂, or Nb₂O₅/SiO₂.

In the light-reflective surface 41B, the reflectance with respect to the peak wavelength of the light irradiated on the light-reflective surface 41B is equal to or more than 90%. The reflectance may be equal to or more than 95%. The reflectance may be equal to or more than 99%. The light reflectance is equal to or less than 100% or is less than 100%.

### Protective Element 50

The protective element 50 has an upper surface 51A, a lower surface 51B, and one or more lateral surfaces 51C. The shape of the protective element 50 is a rectangular parallelepiped. The shape of the protective element 50 need not be a rectangular parallelepiped.

The protective element 50 hinders breakage of a specific element (for example, the light-emitting element 20) as a result of flowing of an excessive current through the element. The protective element 50 is, for example, a Zener diode. A Zener diode formed of Si can be used.

### Wiring Line 60

The wiring line 60 is a linear conductive material having bonding portions at both ends. The bonding portions at both ends serve as portions for bonding with other components. The wiring line 60 is used for electrical connection between two components. The wiring line 60 is, for example, a metal wire. The metal used can be, for example, gold, aluminum, silver, or copper.

### Optical Member 70

The optical member 70 has an upper surface 71A, a lower surface 71B, and one or more lateral surfaces 71C. The optical member 70 imparts an optical action to light that is incident on the optical member 70. Examples of the optical action imparted to the light by the optical member 70 include condensing, collimation, diffusion, polarization control, diffraction, multiplexing, light guiding, reflection, and wavelength conversion.

The optical member 70 has an optical action surface that imparts the optical action. The upper surface 71A, the lower surface 71B, or the lateral surface 71C can serve as the optical action surface. Alternatively, the optical action surface may be provided at a position different from the upper surface 71A, the lower surface 71B, or the lateral surface 71C. For example, the optical action surface may be formed not on a surface of the optical member 70 but on an inner side of the optical member 70.

The upper surface 71A and the lower surface 71B are flat surfaces. The outer shape of the optical member 70 in a top view is rectangular. The outer shape of the optical member 70 in a top view need not be rectangular. The lower surface 71B is a flat surface. The shape of the lower surface 71B is rectangular. The shape of the lower surface 71B need not be rectangular.

The optical member 70 has light transmissivity. In the optical member 70, the light transmittance with respect to the peak wavelength of light incident on the optical member 70 is equal to or more than 80%. The optical member 70 may include a region having light transmissivity and a region having no light transmissivity (hereinafter, referred to as a non-light transmitting region). In the non-light-transmitting region, the light transmittance with respect to the peak wavelength of light incident on the optical member 70 is equal to or less than 50%. The optical member 70 can be formed using, for example, glass such as BK7.

For example, the optical member 70 is a wave plate. The wave plate emits light having polarization different from that of incident light. Examples of the wave plate include a 1/2 wave plate that rotates the polarization direction of linearly polarized light and a 1/4 wave plate that converts linearly polarized light into circularly polarized light. The wave plate used may be, for example, a 1/2 wave plate.

### Spacer 80

The spacer 80 has an upper surface 81A and a lower surface 81B. The spacer 80 has a lateral surface 81C. In a top view, the outer edge shape of the spacer 80 is a circular-like shape or an elliptical-like shape. The spacer 80 has a cylindrical-like shape or an elliptical cylindrical-like shape. In a top view, the outer edge shape of the spacer 80 may not be circular or elliptical. The shape of the spacer 80 is not limited to the cylindrical-like shape and the elliptic cylindrical-like shape.

In a top view, the spacer 80 is included in a square of 500 μm×500 μm. In a top view, the spacer 80 can be included in a square of 150 μm×150 μm. The thickness of the spacer 80 in a vertical direction is in a range from 10 μm to 100 μm. The thickness of the spacer 80 in a vertical direction can be in a range from 30 μm to 50 μm.

The upper surface 81A of the spacer 80 is a flat surface. The upper surface of the spacer 80 may not be a flat surface. For example, the upper surface 81A of the spacer 80 may be a curved surface. For example, the upper surface 81A of the spacer 80 may be a curved surface and a convex surface, or may be a curved surface and a concave surface.

The spacer 80 can be formed using, for example, a metal material as a main material. Examples of the metal material serving as the main material of the spacer 80 include single-component metals such as Cu, Ag, Ni, Au, Sn, Ti, and Pd, and alloys containing any of these metals. The shape of the spacer 80 is stabilized by using a metal.

### Bonding Portion 90

The bonding portion 90 refers to a state in which the adhesive AD is cured. For example, an adhesive containing a resin is used as the adhesive AD forming the bonding portion 90. Examples of the adhesive containing a resin include an ultraviolet curable resin and a thermosetting resin. The adhesive AD may be applied to a plurality of locations. Thus, a plurality of bonding portions 90 can be formed by a bonding process. The adhesive AD forming the bonding portion 90 is not limited to one type of adhesive. For example, a plurality of types of adhesives AD may be applied to different positions to form a plurality of bonding portions 90.

Subsequently, the light-emitting device 1 will be described.

### Light-Emitting Device 1

In the light-emitting device 1, one or each light-emitting element 20 is disposed in the internal space of the package 10. One or each light-emitting element 20 is disposed on the base 11. One or each light-emitting element 20 is disposed on the first upper surface 11A. One or each light-emitting element 20 is disposed in a sealed space surrounded by the base 11 and the lid body 14.

Light emitted from one or each light-emitting element 20 is incident on the lid body 14. The light incident on the lower surface 14B of the lid body 14 passes through the lid body 14 and is emitted from the upper surface 14A of the lid body 14. The light emitted from the lid body 14 is divergent light.

In the light-emitting device 1, one or each light-emitting element 20 is disposed on the submount 30. One or each light-emitting element 20 is disposed on the first upper surface 11A via the submount 30. One or each submount 30 is bonded to the first upper surface 11A at the lower surface 31B and bonded to the light-emitting element 20 at the upper surface 31A. The number of light-emitting elements 20 disposed on one submount 30 is one or more.

One or each light-emitting element 20 has the light-emitting surface 22 at the lateral surface 21C and emits light from the light-emitting surface 22 in a lateral direction. One or each light-emitting element 20 emits light in a first direction. The first direction may be parallel to a direction perpendicular to the light-emitting surface 22. In the light-emitting device 1 illustrated by the drawings, the positive direction of Y can be regarded as the first direction.

In the light-emitting device, one or each reflective member 40 is disposed on the base 11. One or each reflective member 40 is disposed in the internal space of the package 10. One or each reflective member 40 is disposed on the first upper surface 11A. One or each reflective member 40 is disposed at a position spaced apart from the light-emitting element 20 in the first direction.

One or each reflective member 40 reflects light emitted from the light-emitting element 20. One or each light-emitting element 20 emits light toward the light-reflective surface 41B of the reflective member 40. The light reflected by the light-reflective surface 41B is incident on the lid body 14. The light emitted from the light-emitting element 20 may be incident on the lid body 14 without using the reflection by the reflective member 40.

One or each reflective member 40 is spaced apart from the inner lateral surface 11E of the package 10. One or each reflective member 40 is disposed such that the light-reflective surface 41B faces the light-emitting surface 22 of the light-emitting element 20 and a lateral surface opposite to the light-reflective surface 41B faces the inner lateral surface 11E.

In a top view, the length of the light-emitting element 20 is greater than the length of the reflective member 40 in the first direction. In a top view, the length of the submount 30 is greater than the length of the reflective member 40 in the first direction.

In a top view, a virtual line that passes through a widthwise midpoint of the first upper surface 11A in the first direction and is parallel to a second direction perpendicular to the first direction passes through the light-emitting element 20 and does not pass through the reflective member 40. In a top view, a virtual line that passes through a widthwise midpoint of the inner frame of the second upper surface 11C in the first direction and is parallel to the second direction perpendicular to the first direction passes through the light-emitting element 20 and does not pass through the reflective member 40.

One or each light-emitting element 20 is a semiconductor laser element, and the light emitted from the light-emitting surface 22 and passing through the optical axis is reflected by the reflective member 40 in a direction perpendicular to the first upper surface 11A.

In the case of realizing a small light-emitting device 1, the width of the first upper surface 11A in the first direction is close to the sum of the length of the light-emitting element 20 or the submount 30 in the first direction and the length of the reflective member 40 in the first direction. Therefore, the light-reflective surface 41B is disposed at a position shifted from the center of the first upper surface 11A, and the light passing through the optical axis is emitted from the lid body 14 at a position shifted from the center of the lid body 14. In addition, since the divergent light is emitted from the lid body 14, the region where the main portion of the light is irradiated on the upper surface 14A of the lid body 14 is also shifted in the first direction from the center of the light-emitting device 1 in a top view.

In the light-emitting device 1, one or each protective element 50 is disposed on the base 11. One or each protection element 50 is disposed in the internal space of the package 10. One or more protective elements 50 include the protective element 50 disposed on the upper surface 11G of the step portion 11F of the base 11. The protective element 50 protects the light-emitting element 20 disposed on the base 11.

The light-emitting device 1 includes a plurality of wiring lines 60 electrically connected to the light-emitting element 20. The wiring lines 60 include one or more wiring lines 60 bonded to the light-emitting element 20. The wiring lines 60 include one or more wiring lines 60 bonded to the first step portion 11F1 of the base 11. The wiring lines 60 include one or more wiring lines 60 bonded to the second step portion 11F2 of the base 11.

The wiring lines 60 are bonded to the first wiring portion 12A1 and electrically connect the light-emitting element 20 to the second wiring portion 12A2.

In the light-emitting device 1, one or more spacers 80 are disposed on the upper surface 14A. One or more spacers 80 are provided on the upper surface 14A. The one or more spacers 80 include one or more first spacers 80A and one or more second spacers 80B.

When the upper surface 14A is divided into the first region R1 and the second region R2 by a virtual line that passes through a widthwise midpoint of the upper surface 14A in the first direction and is parallel to the second direction, one or each first spacer 80A is disposed in the first region R1, and one or each second spacer 80B is disposed in the second region R2. In a top view, the reflective member 40 is included in the first region R1. In a top view, the reflective member 40 is not included in the second region R2. The first region R1 is located in the first direction with respect to the second region R2, and the second region R2 is located in the direction opposite to the first direction with respect to the first region R1.

One or each second spacer 80B is disposed on the upper surface 14A at a position spaced apart from the first spacer 80A in a direction opposite to the first direction. In the light-emitting device 1 illustrated by the drawings, the negative direction of Y can be regarded as the direction opposite to the first direction. One or each spacer 80 is disposed at a position spaced apart from an irradiation region where the main portion of the light is irradiated on the upper surface 14A in a fast axis direction of the light in the irradiation region. One or each first spacer 80A is disposed at a position spaced apart from the irradiation region in the first direction, and one or each second spacer 80B is disposed at a position spaced apart from the irradiation region in a direction opposite to the first direction.

One or each first spacer 80A is disposed at a position overlapping the second upper surface 11C in a top view. One or each second spacer 80B is disposed at a position overlapping the second upper surface 11C in a top view. When the spacers 80 are disposed in this manner, the spacers 80 are provided outside the optical path of the main portion of the light, and it is possible to realize the light-emitting device 1 in which the spacers 80 are suppressed from obstructing the optical path of the light.

One or each first spacer 80A is disposed at a position spaced apart from the reflective member 40 in the first direction in a top view. One or each second spacer 80B is disposed at a position spaced apart from the light-emitting element 20 in a direction opposite to the first direction in a top view.

As shown in FIG. 7B, when the upper surface 14A is divided into a third region R3 and a fourth region R4 by a virtual line L1 (hereinafter, referred to as a first virtual line L1) which passes through a point at which the light passing through the optical axis is emitted from the light-emitting surface 22 and is parallel to a direction in which the light passing through the optical axis travels from the light-emitting surface 22 in a top view, the one or more first spacers 80A include a first spacer 80A disposed in the third region R3 and a first spacer 80A disposed in the fourth region R4. The one or more first spacers 80A do not include a first spacer 80A passing through the first virtual line L1. The one or more second spacers 80B include a second spacer 80B disposed in the third region R3 and a second spacer 80B disposed in the fourth region R4. The one or more second spacers 80B do not include a second spacer 80B passing through the first virtual line L1.

The first virtual line L1 illustrated by the drawings overlaps the fast axis of the FFP of the light irradiated on the upper surface 14A of the lid body 14. In other words, the first virtual line L1 may be a virtual line that passes through the fast axis of the FFP of the light irradiated on the upper surface 14A of the lid body 14 and is parallel to the fast axis.

The maximum width of one or each spacer 80 in the first direction is in a range from 10 μm to 200 μm. When the spacer has a smaller width while playing a role as a spacer, the ratio of the area where the adhesive AD is in contact with the spacer 80 to the area where the adhesive AD is in contact with the spacer 80 and the lid body 14 can be made smaller, and the area where the adhesive AD is in contact with the lid body 14 can be made relatively larger.

In the light-emitting device 1, the optical member 70 is disposed on the package 10. The optical member 70 is disposed on the lid body 14. The optical member 70 is disposed above the upper surface 14A. The light emitted from the light-emitting element 20 and emitted from the upper surface 14A is incident on the optical member 70. The light incident on the optical member 70 is provided with an optical action and is emitted from the optical member 70. For example, when the optical member 70 is a wave plate, light is emitted from the optical member 70 in a polarization direction different from the polarization direction of light incident on the optical member 70.

The optical member 70 is bonded to the package 10 via the adhesive AD provided between the upper surface 14A of the package 10 and the lower surface 71B of the optical member 70. The adhesive AD is cured to form the bonding portion 90 by the bonding of the package 10 and the optical member 70. In the light-emitting device 1, the bonding portion 90 bonds the lid body 14 and the optical member 70.

The optical member 70 is bonded to the package 10 via the adhesive AD provided on the spacer 80. The bonding portion 90 is provided between the upper surface 14A of the lid body 14 and the lower surface 71B of the optical member 70, and between the upper surface 81A of the spacer 80 and the lower surface 71B of the optical member 70 (see FIG. 5). When the spacer 80 is disposed, the thickness of the adhesive AD can be adjusted by the thickness of the spacer 80, and the adhesive AD can be suppressed from excessively spreading. Therefore, it is possible to realize the light-emitting device 1 in which the adhesive AD or the bonding portion 90 is suppressed from obstructing the optical path of light. In addition, the maximum distance from the spacer 80 to the bonding portion 90 is smaller in a case in which the adhesive AD is provided on the spacer 80 than in a case in which the adhesive is provided outside the spacer 80, and thus the light-emitting device 1 can be designed to be compact.

The adhesive AD is provided at a position corresponding to one or each spacer 80. Each bonding portion 90 formed corresponding to one or each spacer 80 may be provided between the upper surface 14A of the lid body 14 and the lower surface 71B of the optical member 70, and between the upper surface 81A of the spacer 80 and the lower surface 71B of the optical member 70.

Regarding the spacer 80 and the bonding portion 90 corresponding to the spacer 80, the spacer 80 is included or embedded in the bonding portion 90 in a top view. In a top view, the outer edge of the spacer 80 is located inside the outer edge of the bonding portion 90. Such an arrangement relationship holds for one or each spacer 80. Thus, the light-emitting device 1 can be designed to be compact.

Regarding the spacer 80 and the bonding portion 90 corresponding to the spacer 80, in a top view, the outer edge of the bonding portion 90 intersects with the virtual straight line passing through the spacer 80 at two positions of a first position P1 and a second position P2 inside the outer edge of the lid body 14, and the centers of the first position P1 and the second position P2 overlap the spacer 80 in a top view (see FIG. 7B). Thus, the light-emitting device 1 can be designed to be compact. In the light-emitting device 1 illustrated by the drawings, the virtual straight line can be a straight line parallel to the X direction.

The bonding portion 90 formed by curing the adhesive AD provided corresponding to the first spacer 80A and the bonding portion 90 formed by curing the adhesive AD provided corresponding to the second spacer 80B are spaced apart from each other. Here, the bonding portion 90 provided in contact with the first spacer 80A is referred to as the first bonding portion 90A, and the bonding portion 90 provided in contact with the second spacer 80B is referred to as the second bonding portion 90B.

The first bonding portion 90A may be provided in one-to-one correspondence with one or more first spacers 80A. That is, the first bonding portion 90A corresponding to any first spacer 80A is spaced apart from all the first bonding portions 90A corresponding to the other first spacers 80A. The adhesive AD provided corresponding to two first spacers 80A may be connected to form one first bonding portion 90A.

The second bonding portion 90B may be provided in one-to-one correspondence with one or more second spacers 80B. That is, the second bonding portion 90B corresponding to any second spacer 80B is spaced apart from all the second bonding portions 90B corresponding to the other second spacers 80B. The adhesive AD provided corresponding to two second spacers 80B may be connected to form one second bonding portion 90B.

Regarding the first spacer 80A and the first bonding portion 90A corresponding to the first spacer 80A, in a top view, the first bonding portion 90A intersects with a virtual straight line passing through the first spacer 80A and parallel to the first direction at two positions of a third position P3 and a fourth position P4, and the distance D1 from the first spacer 80A to the third position P3 is smaller than the distance D2 from the first spacer 80A to the fourth position P4 (see FIG. 17B). In a top view, the distance from the first spacer 80A to the light-emitting element 20 is greater than the distance from the third position P3 to the light-emitting element 20 and smaller than the distance from the fourth position P4 to the light-emitting element 20. Accordingly, the light-emitting device 1 can be realized in which the bonding portion 90 is suppressed from obstructing the optical path of light.

The width of the first bonding portion 90A in the first direction in a top view is more than one time and not more than five times the width of the first spacer 80A in the first direction in a top view. When the width of the first bonding portion 90A in the first direction is suppressed to be four times or less, interference with light by the first bonding portion 90A can be suppressed, and a small light-emitting device can be realized.

A point P5 at which the first bonding portion 90A formed corresponding to the first spacer 80A provided in the third region R3 minimizes the distance from the light-emitting element 20 in the first direction is located at a position 100 μm or more apart from the first virtual line L1 in the second direction. In a case in which the light-emitting element 20 is a semiconductor laser element, the fast axis of light is located on the first virtual line L1 on the lower surface 71B of the optical member 70. Therefore, it is possible to suppress interference of light by the first bonding portion 90A by providing the point P5 at a position spaced apart from the first virtual line L1.

A point P6 at which the first bonding portion 90A formed corresponding to the first spacer 80A provided in the fourth region R4 minimizes the distance from the light-emitting element 20 in the first direction is located at a position 100 μm or more apart from the first virtual line L1 in the second direction. In the light-emitting device 1, there is no first spacer 80A passing through the first virtual line L1. In the light-emitting device 1, there is no first bonding portion 90A that passes through the first virtual line L1.

In a top view, at least a portion of the optical member 70 overlaps at least a portion of the reflective member 40. In a top view, at least a portion of the optical member 70 overlaps at least a portion of the light-emitting element 20. In a top view, at least a portion of one or each spacer 80 overlaps at least a portion of the optical member 70. In a top view, one or each spacer 80 may be covered by the outer edge of the optical member 70.

The one or more first bonding portions 90A include the first bonding portion 90A, at least a portion of which is disposed outside the optical member 70 in a top view. The one or more second bonding portions 90B include the second bonding portion 90B, at least a portion of which is disposed outside the optical member 70 in a top view.

In a top view, the width of the optical member 70 in the first direction is greater than the width of the first upper surface 11A in the first direction. In a top view, the width of the optical member 70 in the second direction is smaller than the width of the first upper surface 11A in the second direction.

In a top view, a portion of the outer edge of the optical member 70 is located between the outer edge of the lid body 14 and the outer edge of the base 11. When the optical member 70 is disposed in this manner, it is possible to provide the adhesive AD such that the bonding portion 90 is close to the outer edge of the lid body 14, and it is easy to avoid interference with light by the bonding portion 90.

In a top view, the lateral surface 71C of the optical member 70 ahead of the light-emitting element 20 in the first direction is located between the lateral surface 14C of the lid body 14 ahead of the light-emitting element 20 in the first direction and the outer lateral surface 11D of the base 11 ahead of the light-emitting element 20 in the first direction.

In a top view, the entire length of the outer edge of the optical member 70 is smaller than the entire length of the outer edge of the lid body 14. In a top view, the size of the optical member 70 may be smaller than the size of the lid body 14. Thus, the light-emitting device 1 can be reduced in weight.

One or each spacer 80 is disposed at a position, apart from the irradiation region of the main portion of the light incident on the lower surface 71B of the optical member 70, in the fast axis direction of the light on the lower surface 71B. One or each first spacer 80A is disposed at a position spaced apart from the irradiation region in the first direction, and one or each second spacer 80B is disposed at a position spaced apart from the irradiation region in a direction opposite to the first direction.

The light-emitting device 1 can be manufactured by a method including: providing the package 10 having the lid body 14 with the upper surface 14A, the light-emitting element 20 disposed in the internal space of the package 10, and one or more spacers 80 each being disposed on the upper surface 14A of the lid body 14 and having the upper surface 81A; providing the adhesive AD to cover the upper surface 81A of one or each spacer 80 in a top view; and bonding the upper surface 14A of the lid body 14 and the lower surface 71B of the optical member 70 via the adhesive AD.

In addition, each of these steps can be executed so that the above-described arrangement relationship is satisfied among a plurality of components included in the light-emitting device 1.

For example, in the step of providing the adhesive AD, as illustrated in FIG. 15, the adhesive AD may be provided on the upper surface 81A of the spacer 80 by controlling a device for application of the adhesive AD from a nozzle and discharging the adhesive AD from the nozzle at a position where the center of the nozzle overlaps the center of the spacer 80 in a top view.

Alternatively, for example, in the step of providing the adhesive AD, as illustrated in FIG. 16, the adhesive AD may be provided on the upper surface 81A of the spacer 80 by controlling a device for application of the adhesive AD from a nozzle and discharging the adhesive AD from the nozzle at a position where the center of the nozzle is shifted from the center of the spacer 80 in a top view.

### Second Embodiment

A light-emitting module 901 according to a second embodiment will be described. FIG. 18 is a view for illustrating an exemplary embodiment of the light-emitting module 901. FIG. 18 is a schematic view of the light-emitting module 901.

The light-emitting module 901 includes one or more first light-emitting devices, one or more second light-emitting devices 2, and a light guide plate 101. The first light-emitting device is the light-emitting device 1 according to the first embodiment. Hereinafter, it is referred to as a first light-emitting device 1. The second light-emitting device 2 is a light-emitting device different from the light-emitting device 1. Specifically, unlike the light-emitting device 1, the second light-emitting device 2 does not include the optical member 70. Therefore, the spacer 80 and the bonding portion 90 for bonding the optical member 70 are also unnecessary. The second light-emitting device 2 can include the other components included in the light-emitting device 1.

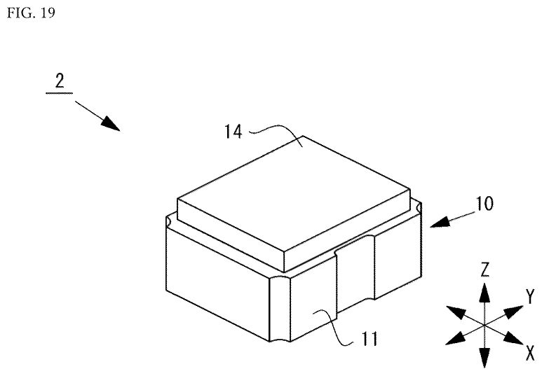

FIGS. 9 to 13 and FIG. 19 are views for illustrating an exemplary embodiment of the second light-emitting device 2. FIG. 9 is a schematic perspective view illustrating the internal structure of the package of the second light-emitting device 2. FIG. 10 is a schematic top view illustrating the internal structure of the package of the second light-emitting device 2. FIG. 11 is a schematic bottom view of the package 10. FIG. 12 is a schematic top view illustrating an arrangement state of a light-emitting element 20 and a submount 30. FIG. 13 is a schematic side view illustrating an arrangement state of the light-emitting element 20 and the submount 30. FIG. 19 is a schematic perspective view of the second light-emitting device 2.

### Light-Emitting Module 901

The color of light emitted from the first light-emitting device 1 is different from the color of light emitted from the second light-emitting device 2. The emission peak wavelength of the light emitted from the first light-emitting device 1 is different from the emission peak wavelength of the light emitted from the second light-emitting device 2. The difference between the emission peak wavelengths of the light emitted from the first light-emitting device 1 and the light emitted from the second light-emitting device 2 is at least 20 nm or more.

The polarization direction of light emitted from a light-emitting element 20 included in the first light-emitting device 1 (hereinafter, the light-emitting element will be referred to as a first light-emitting element) is different from the polarization direction of light emitted from a light-emitting element 20 included in the second light-emitting device 2 (hereinafter, the light-emitting element will be referred to as a second light-emitting element). The optical member 70 included in the first light-emitting device 1 is a wave plate.

The one or more first light-emitting devices 1 and the one or more second light-emitting devices 2 include the first light-emitting device 1 and the second light-emitting device 2 that emit light in the same direction. Here, the expression “emit light in the same direction” refers to that the lights emitted from these devices have the same fast axis direction and the same slow axis direction. Each of the first light-emitting device 1 and the second light-emitting device 2 emits, from the upper surface 14A, light in which the fast axis direction is parallel to the first direction and the slow axis direction is parallel to the second direction. The first light-emitting device 1 and the second light-emitting device 2 are disposed such that they are aligned in the first direction.

The light emitted from the first light-emitting device 1 and the light emitted from the second light-emitting device 2 have the same polarization direction. The light emitted from the first light-emitting device 1 and the light emitted from the second light-emitting device 2 have the same fast axis direction. The polarization direction of the light emitted from the first light-emitting element is changed by the optical member 70 included in the first light-emitting device 1, and the first light-emitting device 1 emits light having the same polarization direction as that of the light emitted from the second light-emitting device 2. Thus, the lights emitted from the first light-emitting device 1 and the second light-emitting device 2 can have the same polarization direction.

The one or more second light-emitting devices 2 may include two second light-emitting devices that emit light of different colors. The one or more second light-emitting devices 2 include two second light-emitting devices 2 that emit light having different emission peak wavelengths. The difference between the emission peak wavelengths in the two second light-emitting devices 2 is at least 20 nm or more.

The one or more first light-emitting devices 1 and the one or more second light-emitting devices 2 include a light-emitting device including a light-emitting element 20 that emits red light, a light-emitting device including a light-emitting element 20 that emits green light, and a light-emitting device including a light-emitting element 20 that emits blue light. For example, the light-emitting module 901 may include a first light-emitting device 1 including the light-emitting element 20 that emits red light, a second light-emitting device 2 including the light-emitting element 20 that emits green light, and a second light-emitting device 2 including the light-emitting element 20 that emits blue light.

The light-emitting module 901 may include a second light-emitting device 2 including the light-emitting element 20 that emits red light, a first light-emitting device 1 including the light-emitting element 20 that emits green light, and a first light-emitting device 1 including the light-emitting element 20 that emits blue light.

Alternatively, the light-emitting module 901 may include a first light-emitting device 1 including the light-emitting element 20 that emits red light, a second light-emitting device 2 including the light-emitting element 20 that emits green light, and a second light-emitting device 2 including the light-emitting element 20 that emits blue light.

The light emitted from the one or more first light-emitting devices 1 and the one or more second light-emitting devices 2 is incident on the light guide plate 101. The light emitted from the first light-emitting device 1 and the light emitted from the second light-emitting device 2 are incident on the light guide plate 101 in a state in which the lights have the same polarization direction.

Although the embodiments according to the present invention have been described above, the light-emitting device and the light-emitting module according to the present invention are not strictly limited to the light-emitting device and the light-emitting module of the embodiments. In other words, the present invention can be achieved without being limited to the outer shape or the structure of the light-emitting device and the light-emitting module disclosed by the embodiments. The present invention can be applied without requiring all the components being provided. For example, in a case in which some of the components of the light-emitting device disclosed by the embodiments are not stated in the claims, the degree of freedom in design by those skilled in the art such as substitutions, omissions, shape deformations, and material changes is allowed for those components, and then it is specified that the invention stated in the claims is applied to those components.

The light-emitting device and the light-emitting module described in the embodiments can be used for a backlight of a head-mounted display or other displays. That is, the field of display can be said to be one form of usage to which the present invention is applied. The present invention is not limited thereto, and can be used in various utilization forms such as a projector, illumination, exposure, and an in-vehicle headlight.

What is claimed is:

1. A light-emitting device comprising:
a package including a lid body having an upper surface;
a light-emitting element disposed in an internal space of the package;
a first spacer disposed on the upper surface of the lid body and having an upper surface;
an optical member disposed above the lid body and having an upper surface and a lower surface; and
a first bonding portion bonding the lid body and the optical member, the first bonding portion being arranged between the upper surface of the lid body and the lower surface of the optical member and between the upper surface of the first spacer and the lower surface of the optical member.

2. The light-emitting device according to claim 1, wherein
the package includes a base having a first upper surface and a second upper surface, the second upper surface surrounding the first upper surface in a top view and being located above the first upper surface, and
the first spacer is disposed at a position overlapping the second upper surface in the top view.

3. The light-emitting device according to claim 1, wherein
the package includes a base having a first upper surface and a second upper surface, the second upper surface surrounding the first upper surface in a top view and being located above the first upper surface,
the lid body is disposed inside an outer edge of the base in the top view, and
a part of an outer edge of the optical member is located between an outer edge of the lid body and the outer edge of the base in the top view.

4. The light-emitting device according to claim 1, wherein
an outer shape of the optical member is rectangular in a top view, and
an entire length of an outer edge of the optical member is smaller than an entire length of an outer edge of the lid body in the top view.

5. The light-emitting device according to claim 1, further comprising
a reflective member disposed at a position spaced apart from the light-emitting element in a first direction and configured to reflect light emitted from the light-emitting element, wherein
the first spacer is disposed at a position spaced apart from the reflective member in the first direction in a top view.

6. The light-emitting device according to claim 5, further comprising:
a second spacer disposed on the upper surface of the lid body at a position spaced apart from the first spacer in a direction opposite to the first direction in the top view, the second spacer having an upper surface; and
a second bonding portion bonding the lid body and the optical member, wherein
the second bonding portion is provided between the upper surface of the lid body and the lower surface of the optical member and between the upper surface of the second spacer and the lower surface of the optical member, and
the second spacer is disposed at a position spaced apart from the light-emitting element in the direction opposite to the first direction in the top view.

7. The light-emitting device according to claim 5, wherein
a width of the first bonding portion in the first direction in a top view is more than one time and not more than five times a width of the first spacer in the first direction in the top view.

8. The light-emitting device according to claim 5, wherein
the light-emitting element is a semiconductor laser element configured to emit light having a far-field pattern with an elliptical shape,
the optical member is a wave plate, and
the first spacer is disposed at a position, spaced apart from an irradiation region of a main portion of the light incident on the lower surface of the optical member, in a fast axis direction of the light on the lower surface of the optical member.

9. The light-emitting device according to claim 1, wherein
an outer edge of the first bonding portion intersects with a virtual straight line passing through the first spacer at a first position and a second position in a top view, and a center between the first position and the second position overlaps the first spacer in the top view.

10. The light-emitting device according to claim 9, wherein
the first position and the second position are disposed inside an outer edge of the lid body in the top view.

11. The light-emitting device according to claim 1, wherein
an outer edge of the first bonding portion intersects with a virtual straight line passing through the first spacer at a third position and a fourth position in a top view, and a distance from the first spacer to the third position is smaller than a distance from the first spacer to the fourth position.

12. A light-emitting module comprising:
the light-emitting device according to claim 8 as a first light-emitting device;
a second light-emitting device including no wave plate; and
a light guide plate on which light emitted from the first light-emitting device and light emitted from the second light-emitting device are incident in a state in which the lights have the same polarization direction and the same fast axis direction, wherein
the first light-emitting device and the second light-emitting device are aligned in the fast axis direction.

13. A method for manufacturing a light-emitting device, the method comprising:
providing
a package including a lid body having an upper surface,
a light-emitting element disposed in an internal space of the package, and
a first spacer disposed on the upper surface of the lid body and having an upper surface;
providing an adhesive to cover the upper surface of the first spacer in a top view; and
bonding the upper surface of the lid body to a lower surface of an optical member via the adhesive.
